(19) United States
(12) Patent Application Publication
(10) Pub. No.: US 2024/0297090 A1
(43) Pub. Date: Sep. 5, 2024

(54) PACKAGE STRUCTURE

(71) Applicant: Advanced Semiconductor Engineering, Inc., Kaohsiung (TW)

(72) Inventors: Jui-Shan HSU, Kaohsiung (TW); Kuang-Hsiung CHEN, Kaohsiung (TW); Yu-Wei LIANG, Kaohsiung (TW)

(73) Assignee: Advanced Semiconductor Engineering, Inc., Kaohsiung (TW)

(21) Appl. No.: 18/116,269

(22) Filed: Mar. 1, 2023

(51) Int. Cl. H01L 23/36; H01L 23/31; H01L 23/42

(52) U.S. Cl. CPC H01L 23/36; H01L 23/3128; H01L 23/42; H01L 24/16; H01L 24/32; H01L 24/73; H01L 2224/16227; H01L 2224/32225; H01L 2224/73204

(57) ABSTRACT

A package structure is provided. The package structure includes an electronic component, a heat dissipating element, and an adhesive layer. The heat dissipating element is disposed over the electronic component. The adhesive layer is disposed between the electronic component and the heat dissipating element and spaced apart from the electronic component by a first space. The first space is configured to reduce a thermal conductive region between the electronic component and the heat dissipating element occupied by the adhesive layer.

### BACKGROUND

### 1. Field of the Disclosure

The present disclosure relates to a package structure, and to a package structure including a heat dissipating element.

### 2. Description of the Related Art

In a package structure, a heat dissipating element is utilized to dissipate a heat generated from electronic component(s). A thermal conductive layer may be utilized to reduce the thermal resistance between the electronic component and the heat dissipating element. However, the adhesion ability of the thermal conductive layer is not sufficient so that a delamination between the thermal conductive may occur. Further, when the thermal conductive layer is replaced by an adhesive layer which has a greater adhesion ability, the thermal resistance is increased so that the performance of the package structure is degraded. Therefore, a new package structure is required to address the aforesaid issues.

### SUMMARY

In some embodiments, a package structure includes an electronic component, a heat dissipating element, and an adhesive layer. The heat dissipating element is disposed over the electronic component. The adhesive layer is disposed between the electronic component and the heat dissipating element and spaced apart from the electronic component by a first space. The first space is configured to reduce a thermal conductive region between the electronic component and the heat dissipating element occupied by the adhesive layer.

In some embodiments, a package structure includes an electronic component, an encapsulant, a heat dissipating element, a thermal conductive layer, and a block layer. The electronic component includes a top surface and a lateral surface abutting the top surface. The encapsulant encapsulates the electronic component and has a first surface exposing a top surface of the electronic component. An elevation of a first portion of the first surface is lower than that of the top surface of the electronic component. The heat dissipating element is disposed over the first surface of the encapsulant. The thermal conductive layer is disposed over the first portion of the encapsulant and abutting the lateral surface of the electronic component, and configured to guide a heat generated from the lateral surface of the electronic component to the heat dissipating element. The block layer abuts the lateral surface of the electronic component.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a top view of a package structure according to some embodiments of the present disclosure.

FIG. 2 illustrates a cross-sectional view taken along line A-A′ of the package structure of FIG. 1.

FIG. 3 illustrates a cross-sectional view of an example of a package structure according to some embodiments of the present disclosure.

FIG. 4 illustrates a cross-sectional view of an example of a package structure according to some embodiments of the present disclosure.

FIG. 5 illustrates a cross-sectional view of an example of a package structure according to some embodiments of the present disclosure.

FIG. 6 illustrates a cross-sectional view of an example of a package structure according to some embodiments of the present disclosure.

FIG. 7 illustrates a cross-sectional view of an example of a package structure according to some embodiments of the present disclosure.

FIG. 8 illustrates a cross-sectional view of an example of a package structure according 47:

to some embodiments of the present disclosure.

FIG. 9 illustrates a cross-sectional view of an example of a package structure according to some embodiments of the present disclosure.

FIG. 10 illustrates a cross-sectional view of an example of a package structure according to some embodiments of the present disclosure.

FIG. 11 illustrates a cross-sectional view of an example of a package structure according to some embodiments of the present disclosure.

FIG. 12 illustrates a cross-sectional view of an example of a package structure according to some embodiments of the present disclosure.

FIG. 13 illustrates a top view of a package structure according to some embodiments of the present disclosure.

FIG. 14 illustrates a top view of a layout of an adhesive layer of a package structure according to some embodiments of the present disclosure.

FIG. 15 illustrates a top view of a layout of an adhesive layer of a package structure according to some embodiments of the present disclosure.

FIG. 16 illustrates a top view of a package structure according to some embodiments of the present disclosure.

FIG. 17 illustrates a top view of a package structure according to some embodiments of the present disclosure.

FIG. 18 illustrates a cross-sectional view taken along line B-B′ of the package structure of FIG. 17.

FIG. 19 illustrates a cross-sectional view of an example of a package structure according to some embodiments of the present disclosure.

FIG. 20 illustrates one or more stages of an example of a method for manufacturing a package structure according to some embodiments of the present disclosure.

FIG. 21 illustrates one or more stages of an example of a method for manufacturing a package structure according to some embodiments of the present disclosure.

FIG. 22 illustrates one or more stages of an example of a method for manufacturing a package structure according to some embodiments of the present disclosure.

FIG. 23 illustrates one or more stages of an example of a method for manufacturing a package structure according to some embodiments of the present disclosure.

FIG. 24 illustrates a top view of a layout of an adhesive material and a thermal conductive material at the stage as shown in FIG. 23 according to some embodiments of the present disclosure.

FIG. 25 illustrates a top view of a layout of an adhesive material and a thermal conductive material at the stage as shown in FIG. 23 according to some embodiments of the present disclosure.

FIG. 26 illustrates a top view of a layout of an adhesive material and a thermal conductive material at the stage as shown in FIG. 23 according to some embodiments of the present disclosure.

FIG. 27 illustrates one or more stages of an example of a method for manufacturing a package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

At least some embodiments of the present disclosure provide for a package structure which has an improved crack resistance. In some embodiments, an assembly structure includes such package structure so as to improve a reliability or a yield thereof. At least some embodiments of the present disclosure further provide for techniques for manufacturing the package structure and the assembly structure.

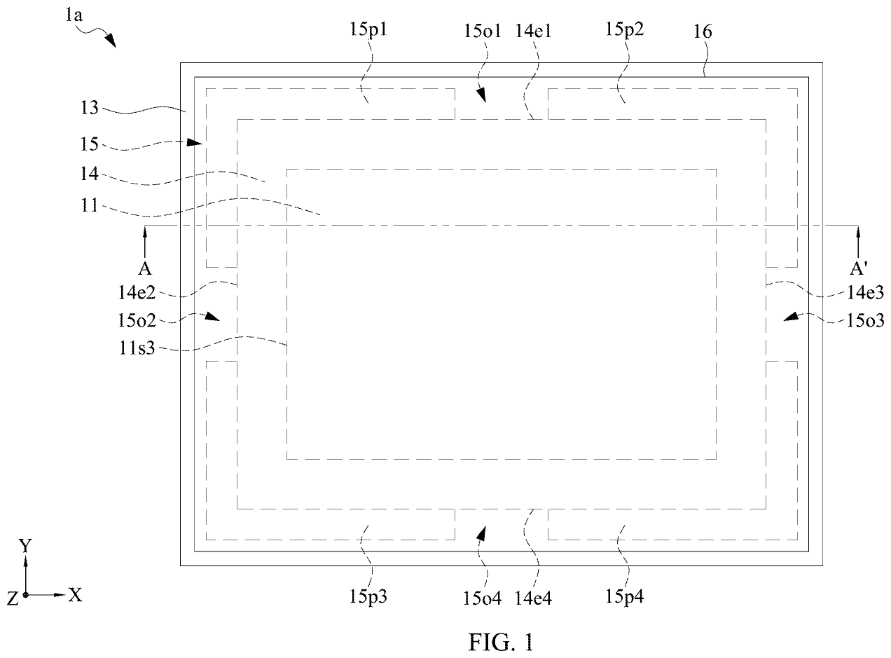

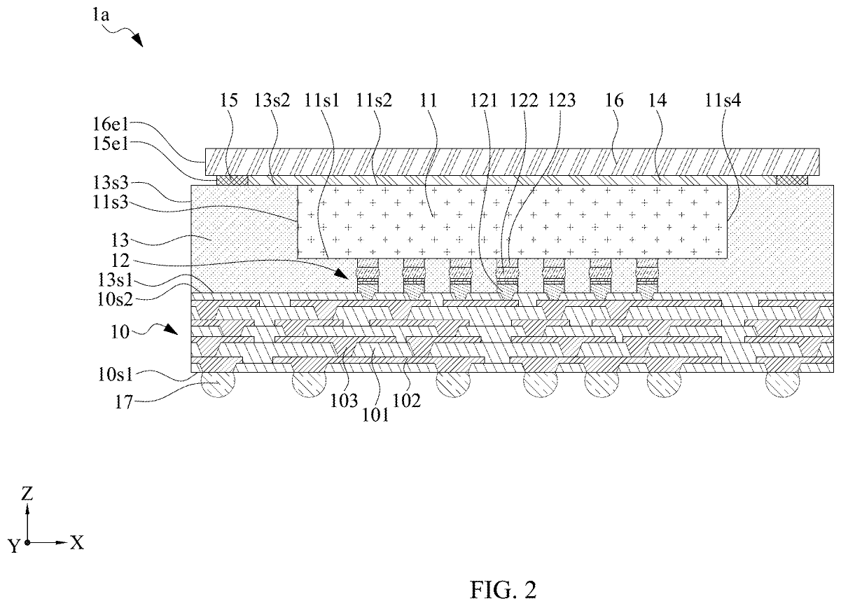

FIG. 1 illustrates a top view of a package structure 1a according to some embodiments of the present disclosure. FIG. 2 illustrates a cross-sectional view taken along line A-A′ of the package structure 1a of FIG. 1. The package structure 1a may include a carrier 10, an electronic component 11, electrical connections 12, an encapsulant 13, a thermal conductive layer 14, an adhesive layer 15, a heat dissipating element 16, and electrical connections 17.

As shown in FIG. 1, the thermal conductive layer 14 may cover the electronic component 11. The thermal conductive layer 14 may exceed a surface (or an edge or a lateral surface) of the electronic component 11. The adhesive layer 15 may enclose and/or accommodate the thermal conductive layer 14. The adhesive layer 15 may be free from overlapping the electronic component 11. The adhesive layer 15 may overlap the encapsulant 13. In some embodiments, the adhesive layer 15 may include a plurality of segments 15p1, 15p2, 15p3, and 15p4. In some embodiments, the segments 15p1, 15p2, 15p3, and 15p4 may be separated from each other. Each of the segments 15p1, 15p2, 15p3, and 15p4 may have an L-shaped profile (or L shape) or other suitable profiles. Each of the segments 15p1, 15p2, 15p3, and 15p4 may function as a block wall. In some embodiments, the segments 15p1, 15p2, 15p3, and 15p4 of the adhesive layer 15 may define a plurality of openings (or channels) 15o1, 15o2, 15o3, and 15o4. A side 14e1 (or a lateral surface) of the thermal conductive layer 14 may face the opening (or channel) 15o1. A side 14e2 (or a lateral surface) of the thermal conductive layer 14 may face the opening (or channel) 15o2. A side 14e3 (or a lateral surface) of the thermal conductive layer 14 may face the opening (or channel) 15o3. A side 14e4 (or a lateral surface) of the thermal conductive layer 14 may face the opening (or channel) 15o4. In some embodiments, a portion of the side 14e1, 14e2, 14e3, and 14e4 of the thermal conductive layer 14 may be exposed from openings (or channels) 15o1, 15o2, 15o3, and 15o4 of the adhesive layer 15, respectively. The openings (or channels) 15o1, 15o2, 15o3, and 1504 of the adhesive layer 15 may be configured to reduce voids between the adhesive layer 15 and the thermal conductive layer 14. Although FIG. 1 illustrates that the adhesive layer 15 includes four segments and defines four openings (or channels), the amounts of the segments and openings (or channels) are not limited in the present disclosure. In some embodiments, the opening (or channel) 15o1 may be aligned with the opening (or channel) 15o4 along the Y direction. In some embodiments, the opening (or channel) 15o1 may be at least partially overlap the opening (or channel) 15o4 along the Y direction. In some embodiments, the opening (or channel) 15o2 may be aligned with the opening (or channel) 15o3 along the X direction. In some embodiments, the opening (or channel) 15o2 may be at least partially overlap the opening (or channel) 15o3 along the X direction.

As shown in FIG. 2, the carrier 10 may include a redistribution structure, which includes one or more dielectric layers 101, one or more conductive traces 102, and one or more conductive vias 103. The dielectric layer 101 may include an insulating material, a passivation material, a dielectric material or a solder resist material, such as, for example, a benzocyclobutene (BCB) based polymer or a polyimide (PI). In some embodiments, the dielectric layer 101 may be made of a photoimageable material. The conductive trace 102 may be disposed on or disposed over a surface (e.g., a top surface or a bottom surface) of the dielectric layer 101. The conductive via 103 may be disposed on or disposed over a surface (e.g., a top surface or a bottom surface) of the conductive trace 102. Each of the conductive via 103 may penetrate the corresponding dielectric layer 101. The material of the conductive trace 102 and the conductive via 103 may include, for example, copper, aluminum, titanium, another conductive metal, or an alloy thereof. The carrier 10 may include a surface 10s1 (or a bottom surface) and a surface 10s2 (or a top surface) opposite to the surface 10s1. The bottom surface of the bottommost dielectric layer 101 may be defined as the surface 10s1 of the carrier 10. The top surface of the topmost dielectric layer 101 may be defined as the surface 10s2 of the carrier 10.

The electronic component 11 may be disposed on or disposed over the surface 10s2 of the carrier 10. The electronic component 11 may be a chip or a die including a semiconductor substrate, one or more integrated circuit (IC) devices and one or more overlying interconnection structures therein. The IC devices may include active devices such as transistors and/or passive devices such as resistors, capacitors, inductors, or a combination thereof. For example, the electronic component 11 may include a system on chip (SoC). For example, the electronic component 11 may include a radiofrequency IC (RFIC), an application-specific IC (ASIC), a central processing unit (CPU), a microprocessor unit (MPU), a graphics processing unit (GPU), a microcontroller unit (MCU), a field-programmable gate array (FPGA), or another type of IC. The electronic component 11 may have a surface 11s1 (or a bottom surface) and a surface 11s2 (or a top surface) opposite to the surface 11s1. The surface 11s1 may face the carrier 10 and function as an active surface of the electronic component 11. The surface 11s2 may function as a backside surface of the electronic component 11. The surface 11s2 of the electronic component 11 may be exposed from the encapsulant 13. The electronic component 11 may have a surface 11s3 (or a lateral surface) extending between the surfaces 11s1 and 11s2. The surface 11s3 may abut the surface 11s2. The electronic component 11 may have a surface 11s4 (or a lateral surface) extending between the surfaces 11s1 and 11s2. The surface 11s4 may be opposite to the surface 11s3.

The electrical connections 12 may be disposed on or disposed over the surface 11s1 of the electronic component 11. The electrical connections 12 may be disposed between the surface 10s2 of the carrier 10 and the surface 11s1 of electronic component 11. The electrical connection 12 may be configured to electrically connect the carrier 10 and the electronic component 11. In some embodiments, the electrical connection 12 may include a pad 121, a conductive element 122, and an electrical contact 123. The pad 121 may be disposed on or disposed over the surface 10s2 of the carrier 10. The pad 121 may include, for example, copper, aluminum, titanium, another conductive metal, or an alloy thereof. The conductive element 122 may be disposed between the pad 121 and the electrical contact 123. The conductive element 122 may include a solder material, such as alloys of gold and tin solder or alloys of silver and tin solder. The electrical contact 123 may be disposed on or disposed over the surface 11s1 of the electronic component 11. The electrical contact 123 may include copper, gold, platinum, other suitable material.

The encapsulant 13 may be disposed on or disposed over the surface 10s2 of the carrier 10. The encapsulant 13 may encapsulate the electronic component 11. The encapsulant 13 may encapsulate the electrical connections 12. The encapsulant 13 may include a Novolac-based resin, an epoxy-based resin, a silicone-based resin, or another suitable material. Suitable fillers may also be included, such as powdered SiO₂. The encapsulant 13 may have a surface 13s1 (or a bottom surface) and a surface 13s2 (or a top surface) opposite to the surface 13s1. The surface 13s1 of the encapsulant 13 may face and/or be in contact with the carrier 10. In some embodiments, the surface 13s2 of the encapsulant 13 may be substantially level with the surface 11s2 of the electronic component 11. In some embodiments, the surface 13s2 of the encapsulant 13 may be located at an elevation the same as that of the surface 11s2 of the electronic component 11. The electronic component 11 may be exposed from the surface 11s2 of the encapsulant. The encapsulant 13 may have a surface 13s3 (or an edge or a lateral surface) extending between the surfaces 13s1 and 13s2.

In some embodiments, the thermal conductive layer 14 may be disposed on or disposed over the surface 11s2 of the electronic component 11. In some embodiments, the thermal conductive layer 14 may fully cover the surface 11s2 of the electronic component 11. In some embodiments, at least a portion of the thermal conductive layer 14 may be disposed on or disposed over the surface 13s2 of the encapsulant 13. In some embodiments, the thermal conductive layer 14 may vertically overlap both the electronic component 11 and the encapsulant 13. In some embodiments, the thermal conductive layer 14 may be disposed between the electronic component 11 and the heat dissipating element 16. In some embodiments, the thermal conductive layer 14 may be configured to transmit a heat (not shown) generated from the electronic component 11 toward the heat dissipating element 16. For example, the thermal conductive layer 14 may be configured to guide, conduct or dissipate a heat generated from the surface 11s2 and/or 11s3 of the electronic component 11 to the heat dissipating element 16. The coefficient of thermal expansion of the heat dissipating element 16 may be less than the coefficient of thermal expansion of the encapsulant 13. The thermal conductive layer 14 may include a thermal interface material (TIM). The thermal conductive layer 14 may include, for example, silicone, metal, alloy, or other suitable materials. Suitable fillers, such as metal oxide (e.g., aluminum oxide) may also be included.

In some embodiments, the adhesive layer 15 may be disposed on or disposed over the surface 13s2 of the encapsulant 13. In some embodiments, the adhesive layer 15 may contact and/or be in contact with the encapsulant 13. In some embodiments, the adhesive layer 15 may be disposed along the surface 13s3 (or an edge or a lateral surface) of the encapsulant 13. In some embodiments, the adhesive layer 15 may surround or around the thermal conductive layer 14. In some embodiments, the adhesive layer 15 may be located at an elevation the same as that of the thermal conductive layer 14. In some embodiments, the adhesive layer 15 may be free from vertically overlapping the electronic component 11. In some embodiments, the adhesive layer 15 may be free from vertically overlapping the thermal conductive layer 14. In some embodiments, the adhesive layer 15 may be configured to attach and/or join the encapsulant 13 to the heat dissipating element 16. The encapsulant 13 may adhere to the heat dissipating element 16 through the adhesive layer 15. In some embodiments, the adhesive layer 15 may be configured to attach the encapsulant 13 to the heat dissipating element 16 to reduce a warpage of the package structure 1a. That is, since the coefficient of thermal expansion of the heat dissipating element 16 may be less than the coefficient of thermal expansion of the encapsulant 13, the heat dissipating element 16 may inhibit a deformation of the encapsulant 13 during a thermal process, so as to reduce the warpage of the package structure 1a.

In some embodiments, the adhesion ability of the adhesive layer 15 may be greater than that of the thermal conductive layer 14. For example, a force (e.g., a pull force) required to detach the heat dissipating element 16 (or other object) from the adhesive layer 15 may be greater than that from the thermal conductive layer 14.

In some embodiments, a thermal conductivity of the adhesive layer 15 may be less than that of the thermal conductive layer 14. For example, the thermal conductivity of the adhesive layer 15 may be equal to or less than 3 W/mK, and the thermal conductivity of the thermal conductive layer 14 may be equal to or greater than 5 W/mK.

In some embodiments, the rigidity of the adhesive layer 15 may be greater than the thermal conductive layer 14. For example, the Young's modulus of the adhesive layer 15 may be equal to or greater than 6 MPa, and the Young's modulus of the thermal conductive layer 14 may be equal to or less than 1 MPa.

In some embodiments, the heat dissipating element 16 may be disposed on or disposed over the surface 11s2 of the electronic component 11. In some embodiments, the heat dissipating element 16 may be disposed on or disposed over the thermal conductive layer 14. In some embodiments, the heat dissipating element 16 may be in contact with the thermal conductive layer 14. In some embodiments, the heat dissipating element 16 may be disposed on or disposed over the adhesive layer 15. In some embodiments, the heat dissipating element 16 may contact and/or be in contact with the adhesive layer 15. In some embodiments, the heat dissipating element 16 may be spaced apart from the electronic component 11 by the thermal conductive layer 14. In some embodiments, the heat dissipating element 16 may be spaced apart from the encapsulant 13 by the thermal conductive layer 14. In some embodiments, the heat dissipating element 16 may be spaced apart from the encapsulant 13 by the adhesive layer 15. In some embodiments, a portion of the heat dissipating element 16 may be free from vertically overlapping the thermal conductive layer 14. In some embodiments, a portion of the heat dissipating element 16 may be free from vertically overlapping the adhesive layer 15. In some embodiments, an edge 16e1 (or a lateral surface) of the heat dissipating element 16 may exceed an edge 15e1 (or a lateral surface) of the adhesive layer 15. In some embodiments, the surface 13s3 of the encapsulant 13 may exceed the edge 16e1 of the heat dissipating element 16. The heat dissipating element 16 may be configured to transmit a heat of the package structure 1a to the environment. The heat dissipating element 16 may include, for example, a solid metal slug or an electrical insulator coated with metallic film.

The electrical connections 17 may be disposed on or disposed over the surface 10s1 of the carrier 10. The electrical connection 17 may be configured to electrically connect the package structure 1a to an external device (not shown). The electrical connection 17 may include a solder material, such as alloys of gold and tin solder or alloys of silver and tin solder.

In the embodiments of the present disclosure, the package structure 1a includes the thermal conductive layer 14 and the adhesive layer 15. The thermal conductive layer 14 may reduce thermal resistance between the electronic component 11 and the heat dissipating element 16. The adhesive layer 15 may be configured to prevent or reduce the heat dissipating element 16 from delamination from the thermal conductive layer 14. Further, the adhesive layer 15 may function as a block layer, which is configured to accumulate the thermal conductive layer 14 toward the electronic component 11 during manufacturing processes, which will be described later. As a result, the thermal conductive layer 14 may be formed within a desired area, which can further reduce thermal resistance, and thus improve the performance of the package structure 1a.

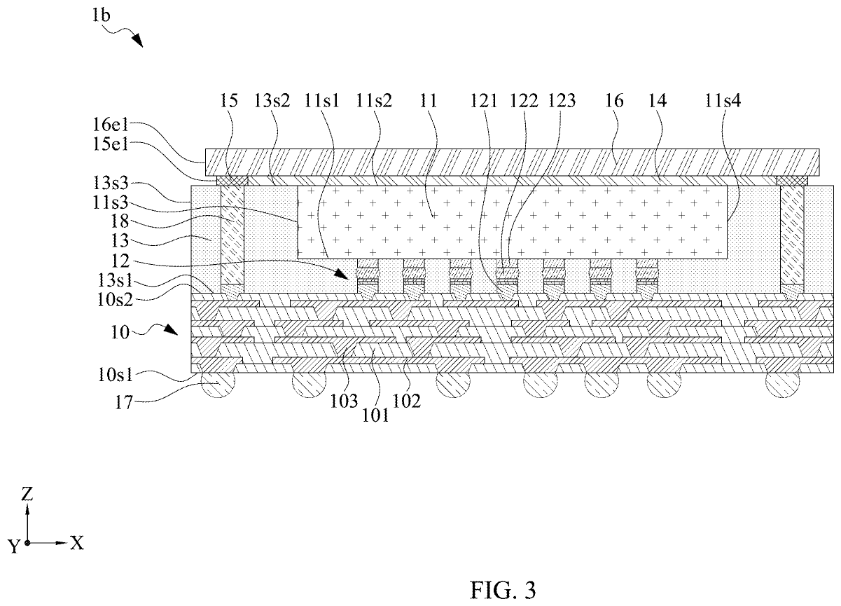

FIG. 3 illustrates a cross-sectional view of an example of a package structure 1b according to some embodiments of the present disclosure. The package structure 1b is similar to the package structure 1a as shown in FIG. 2, and the differences therebetween are described below.

In some embodiments, the package structure 1b may include electrical connections 18. In some embodiments, the electrical connection 18 may be disposed on or disposed over the surface 10s2 of the carrier 10. In such embodiments, the heat dissipating element 16 may include a thermoelectric module. Alternatively, the heat dissipating element 16 may be replaced with a thermoelectric module. Further, the adhesive layer 15 may include a conductive material. Thus, the electrical connection 18 may be electrically connected to the thermoelectric module 16 through the adhesive layer 15. The electrical connection 18 may be thermally connected to and/or electrically connected to the carrier 10. In some embodiments, the electrical connection 18 may penetrate the encapsulant 13. In some embodiments, the electrical connection 18 may be encapsulated by the encapsulant 13. In some embodiments, the electrical connection 18 may be disposed under the adhesive layer 15. The electrical connection 18 may abut the surface 11s3 (or 11s4) of the electronic component 11. The electrical connection 18 may vertically overlap the adhesive layer 15. In some embodiments, the electrical connection 18 may be in contact with the adhesive layer 15. The electrical connection 18 may include a conductive pillar. The electrical connection 18 may include, for example, copper, aluminum, titanium, another conductive metal, or an alloy thereof. In some embodiments, the electrical connection 18 may be configured to transmit a heat from the carrier 10. The electrical connection 18 may further facilitate the heat dissipation of the package structure 1b. The electrical connection 18 may enhance the structural rigidity and prevent the delamination of the heat dissipating element 16 from the encapsulant 13.

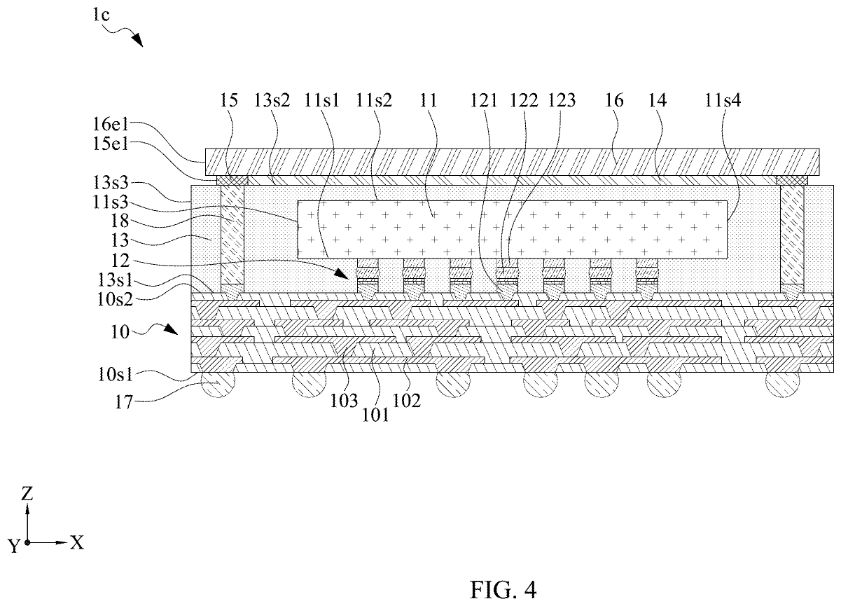

FIG. 4 illustrates a cross-sectional view of an example of a package structure 1c according to some embodiments of the present disclosure. The package structure 1c is similar to the package structure 1b as shown in FIG. 3, and the differences therebetween are described below.

In some embodiments, the surface 11s2 of the electronic component 11 may be spaced apart from the thermal conductive layer 14. In some embodiments, a portion of the encapsulant 13 may be disposed between the surface 11s2 of the electronic component 11 and the thermal conductive layer 14. In some embodiments, the surface 11s2 of the electronic component 11 may be located at an elevation lower than that of the surface 13s2 of the encapsulant 13.

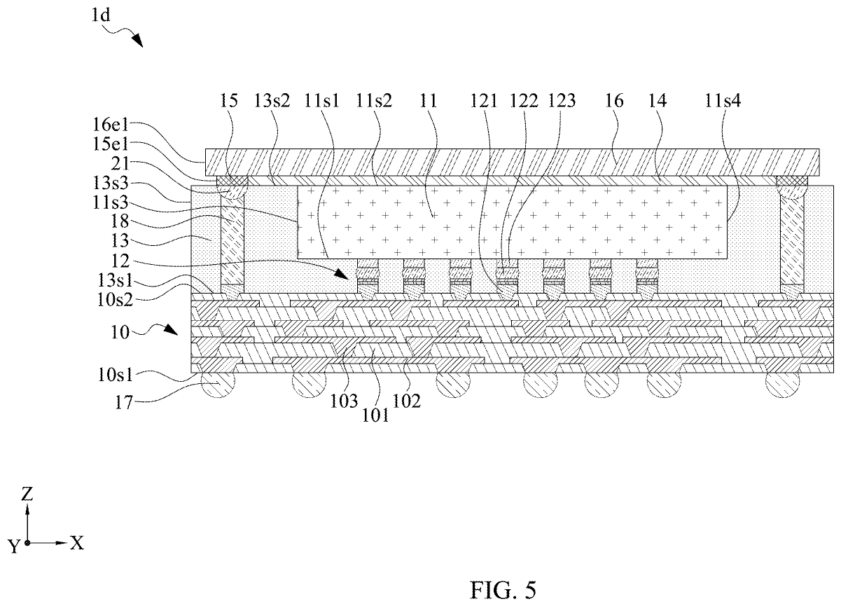

FIG. 5 illustrates a cross-sectional view of an example of a package structure 1d according to some embodiments of the present disclosure. The package structure 1d is similar to the package structure 1b as shown in FIG. 3, and the differences therebetween are described below.

In some embodiments, the package structure 1d may include solder elements 21. In some embodiments, the solder element 21 may be disposed between the adhesive layer 15 and the electrical connection 18. In some embodiments, the solder element 21 may vertically overlap the adhesive layer 15. In some embodiments, the solder element 21 may be thermally connected and/or electrically connected to the electrical connection 18. In some embodiments, the electrical connection 18 may be spaced apart from the adhesive layer 15 by the solder element 21. In some embodiments, the solder element 21 may include a solder material, such as alloys of gold and tin solder or alloys of silver and tin solder. The solder element 21 may be configured to facilitate the heat dissipation of the package structure 1d.

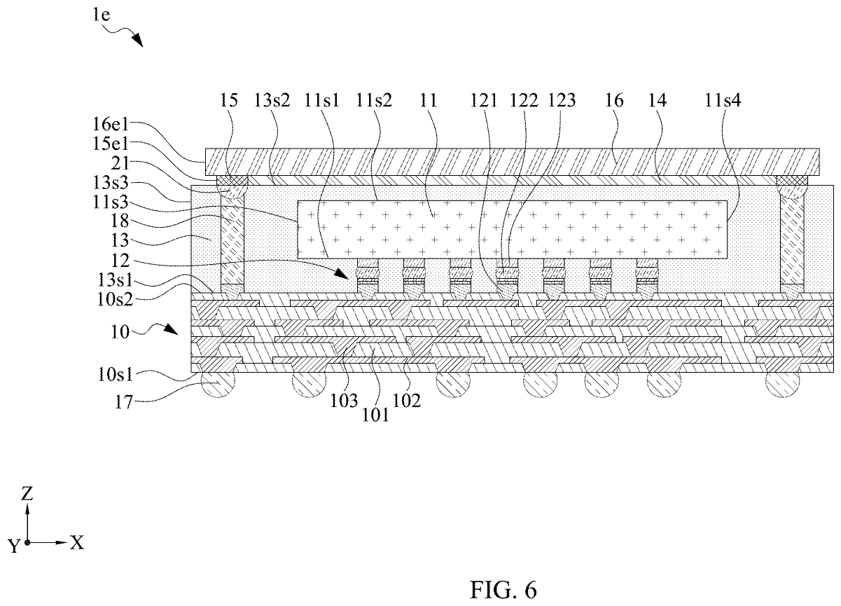

FIG. 6 illustrates a cross-sectional view of an example of a package structure 1e according to some embodiments of the present disclosure. The package structure 1e is similar to the package structure 1d as shown in FIG. 5, and the differences therebetween are described below.

In some embodiments, the surface 11s2 of the electronic component 11 may be spaced apart from the thermal conductive layer 14.

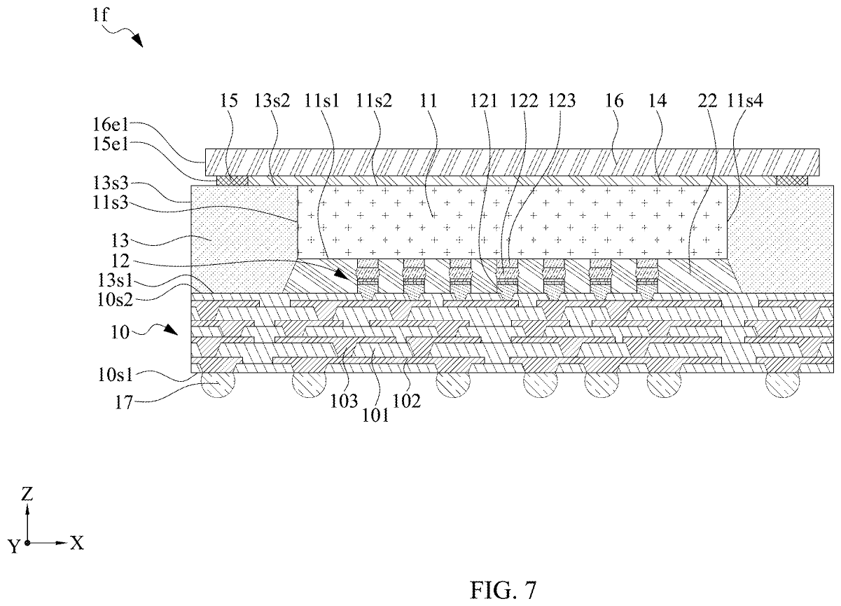

FIG. 7 illustrates a cross-sectional view of an example of a package structure 1f according to some embodiments of the present disclosure. The package structure 1f is similar to the package structure 1a as shown in FIG. 2, and the differences therebetween are described below.

In some embodiments, the package structure 1f may include a protection layer 22. The protection layer 22 may be disposed on or disposed over the surface 11s1 of the electronic component 11. In some embodiments, the protection layer 22 may be disposed between the surface 11s1 of the electronic component 11 and the surface 10s2 of the carrier 10. In some embodiments, the protection layer 22 may encapsulate the electrical connection 12. The protection layer 22 may include an underfill, such as epoxy resin or other suitable materials.

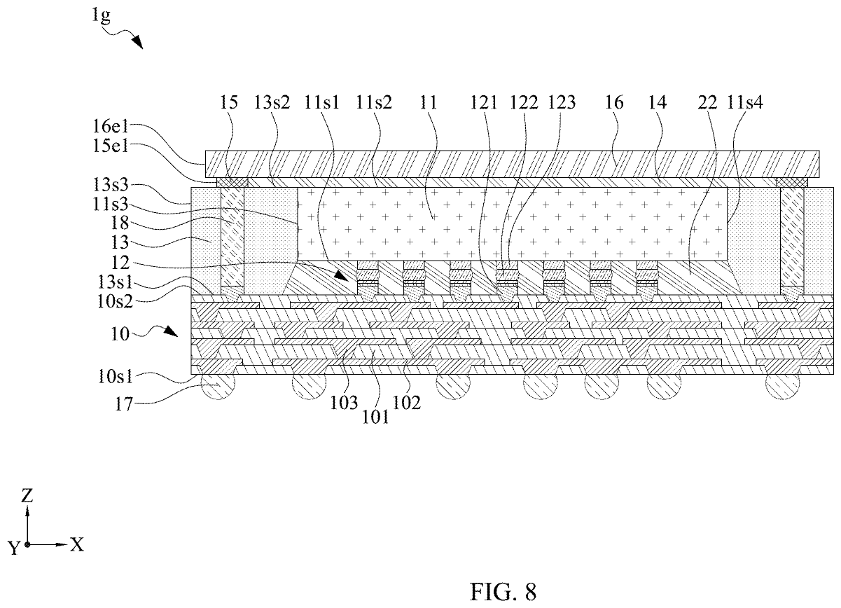

FIG. 8 illustrates a cross-sectional view of an example of a package structure 1g according to some embodiments of the present disclosure. The package structure 1g is similar to the package structure 1f as shown in FIG. 7, and the differences therebetween are described below.

In some embodiments, the package structure 1g may include the electrical connections 18. The electrical connection 18 may penetrate the encapsulant 13. The electrical connection 18 may vertically overlap the adhesive layer 15.

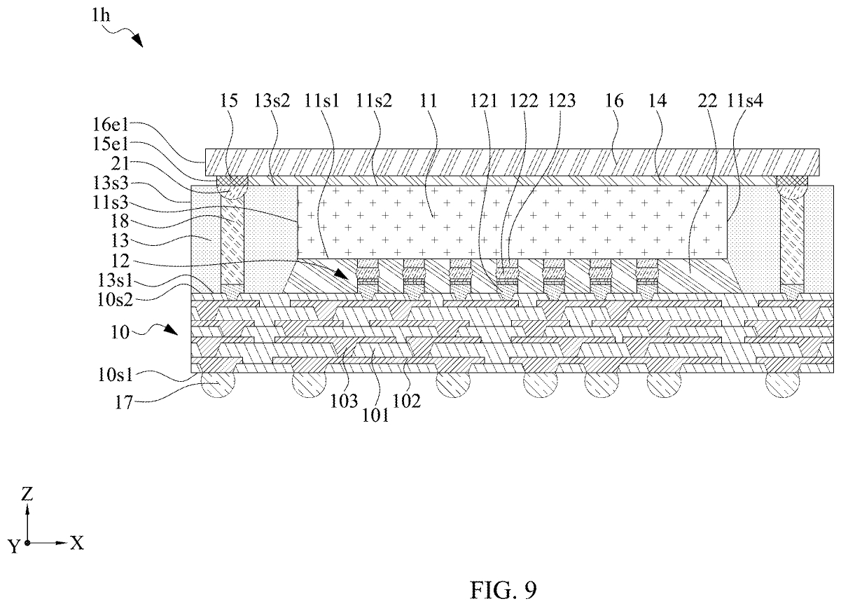

FIG. 9 illustrates a cross-sectional view of an example of a package structure 1h according to some embodiments of the present disclosure. The package structure 1h is similar to the package structure 1g as shown in FIG. 8, and the differences therebetween are described below.

In some embodiments, the package structure 1h may include solder elements 21. The solder element 21 may be disposed between the adhesive layer 15 and the electrical connection 18. The solder element 21 may vertically overlap the adhesive layer 15. The solder element 21 may vertically overlap the electrical connection 18.

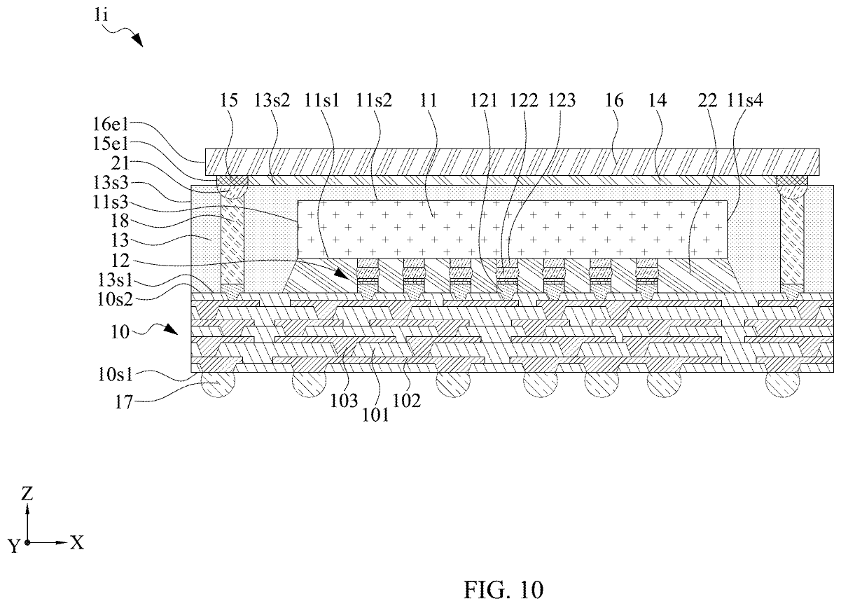

FIG. 10 illustrates a cross-sectional view of an example of a package structure 1i according to some embodiments of the present disclosure. The package structure 1i is similar to the package structure 1h as shown in FIG. 9, and the differences therebetween are described below.

In some embodiments, the surface 11s2 of the electronic component 11 may be spaced apart from the thermal conductive layer 14. The surface 11s2 of the electronic component 11 may be located at an elevation lower than that of the surface 13s2 of the encapsulant 13.

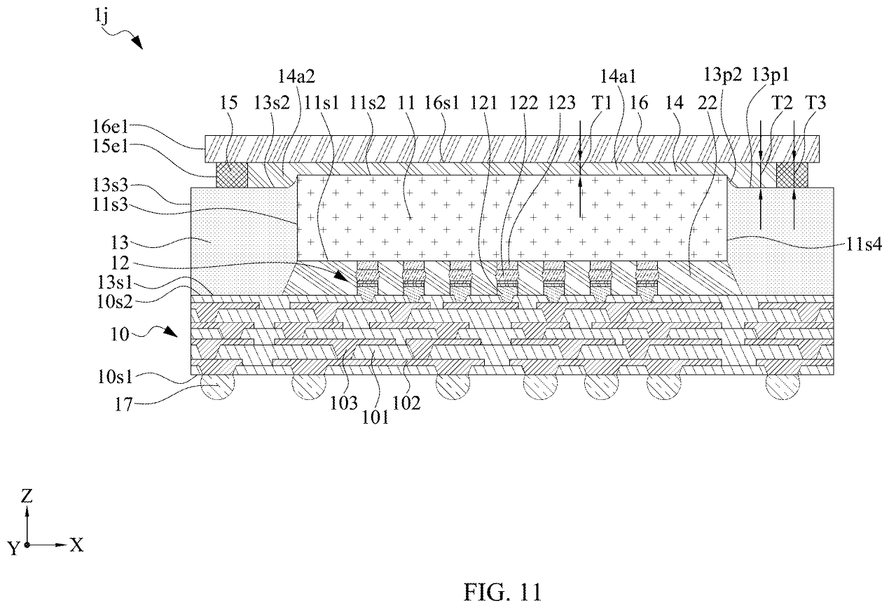

FIG. 11 illustrates a cross-sectional view of an example of a package structure 1j according to some embodiments of the present disclosure. The package structure 1j is similar to the package structure 1a as shown in FIG. 2, and the differences therebetween are described below.

The surface 13s2 of the encapsulant 13 may have a portion 13p1 (or a first portion) and a portion 13p2 (or a second portion). The portion 13p1 of the surface 13s2 of the encapsulant 13 may be a substantially flat surface. The portion 13p2 of the surface 13s2 of the encapsulant 13 may extend between the portion 13p1 of the surface 13s2 of the encapsulant 13 and the surface 11s2 of the electronic component 11. In some embodiments, the portion 13p2 of the surface 13s2 of the encapsulant 13 may include a curved surface. In some embodiments, the surface 11s2 of the electronic component 11 may be higher than the portion 13p1 of the surface 13s2 of the encapsulant 13. In some embodiments, the thermal conductive layer 14 may have uneven thickness. The thermal conductive layer 14 may include a portion 14al which has a thickness T1 over the surface 11s2 of the electronic component 11. The thermal conductive layer 14 may include a portion 14a2 which has a thickness T2 over the portion 13p1 of the surface 13s2 of the encapsulant 13. The portion 14a2 is closer to the adhesive layer 15 than the portion 14al is. In some embodiments, the thickness T2 may be greater than the thickness T1. The adhesive layer 15 may have a thickness T3. In some embodiments, the thickness T3 may be substantially equal to the thickness T2.

The thermal conductive layer 14 may cover an interface (not annotated) between the surface 11s3 of the electronic component 11 and the encapsulant 13. The block layer 15 may be disposed along the interface between the electronic component 11 and the encapsulant 13.

The adhesive layer 15 may abut the surface 11s3 (or surface 11s4) of the electronic component 11. The adhesive layer 15 may function as a block layer and be configured to accumulate the thermal conductive layer 14 toward the surface 11s3 (or surface 11s4) of the electronic component 11. As a result, the thermal conductive layer 14 may guide, conduct or dissipate a heat generated from the surface 11s3 (or surface 11s4) of the electronic component 11 to the heat dissipating element 16.

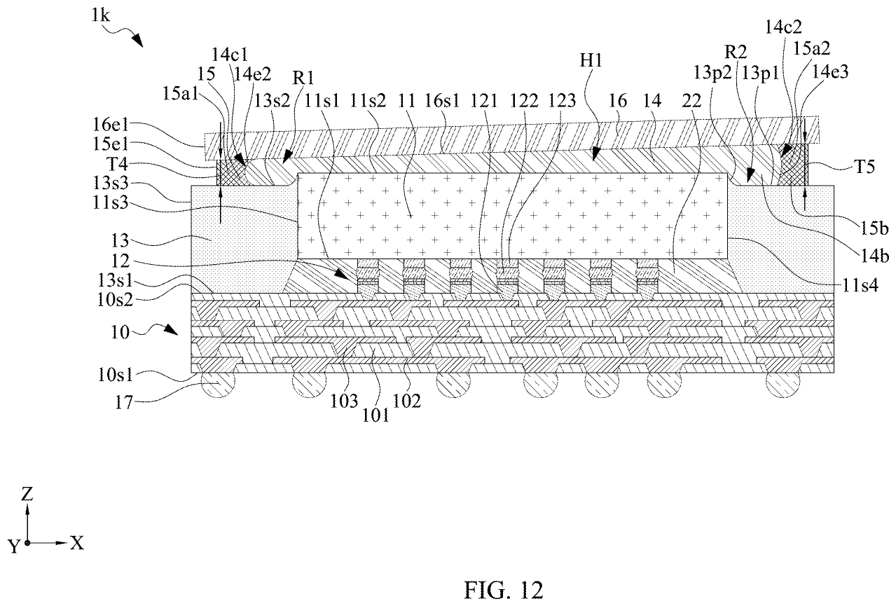

FIG. 12 illustrates a cross-sectional view of an example of a package structure 1k according to some embodiments of the present disclosure. The package structure 1k is similar to the package structure 1j as shown in FIG. 11, and the differences therebetween are described below.

The heat dissipating element 16 may have a surface 16s1 (or a bottom surface). The surface 16s1 of the heat dissipating element 16 may be in contact with the thermal conductive layer 14. The surface 16s1 of the heat dissipating element 16 may be in contact with the adhesive layer 15. In some embodiments, the surface 16s1 of the heat dissipating element 16 may be slanted with respect to the normal direction of the surface 11s2 of the electronic component 11. The surface 16s1 of the heat dissipating element 16 may be nonparallel to the surface 11s2 of the electronic component 11. In some embodiments, the adhesive layer 15 may have an uneven thickness. The adhesive layer 15 may include a portion 15al which has a thickness T4 adjacent to the surface 11s3 of the electronic component 11. The adhesive layer 15 may include a portion 15s2 which has a thickness T5 adjacent to the surface 11s4 of the electronic component 11. In some embodiments, the thickness T4 may be different from the thickness T5. The thickness T4 may be less than the thickness T5. In some embodiments, the side 14e2 may be convex toward the adhesive layer 15. The side 14e2 of the thermal conductive layer 14 may have a curvature 14cl. In some embodiments, the side 14e3 may be convex toward the adhesive layer 15. The side 14e3 of the thermal conductive layer 14 may have a curvature 14c2. In some embodiments, the curvature 14cl may be different from the curvature 14c2. The curvature 14cl may be greater than curvature 14c2. The inner surface of the adhesive layer 15 (or block layer) is concave toward an outer lateral surface of the adhesive layer 15 (or block layer).

In some embodiments, the adhesive layer 15 may be disposed between the electronic component 11 and the heat dissipating element 16. The adhesive layer 15 may be spaced apart from the electronic component 11 by a first space R1. The first space R1 may be configured to reduce a thermal conductive region H1, which is defined as a region between the electronic component 11 and the heat dissipating element 16, occupied by the adhesive layer.

In some embodiments, the adhesive layer 15 includes a portion 15b overlapping the electronic component 11 along the X direction (or along a direction substantially parallel to the surface 11s2 of the encapsulant 11). A second space R2 may be defined between the portion 15b of the adhesive layer 15 and the electronic component 11 along the X direction (or along a direction substantially parallel to the surface 11s2 of the encapsulant 11). The second space R2 may be in communication with the first space R1. Alternatively, the second space R2 may be a portion of the first space R1. In some embodiments, the thermal conductive layer 14 includes a portion 14b located within the second space R2. The portion 14b of the thermal conductive layer 14 may overlap the portion 15b of the adhesive layer 15 along the X direction. The portion 14b of the thermal conductive layer 14 may be configured to guide a heat, generated from the surface 11s3 of the electronic component 11, of the encapsulant 13 to the heat dissipating element 16. The portion 14b of the thermal conductive layer 14 may be configured to guide a heat located within the encapsulant 13 to the heat dissipating element 16. The portion 14b may be configured to guide a heat located at the lateral surface 11s3 of the electronic component 11 to the heat dissipating element 16.

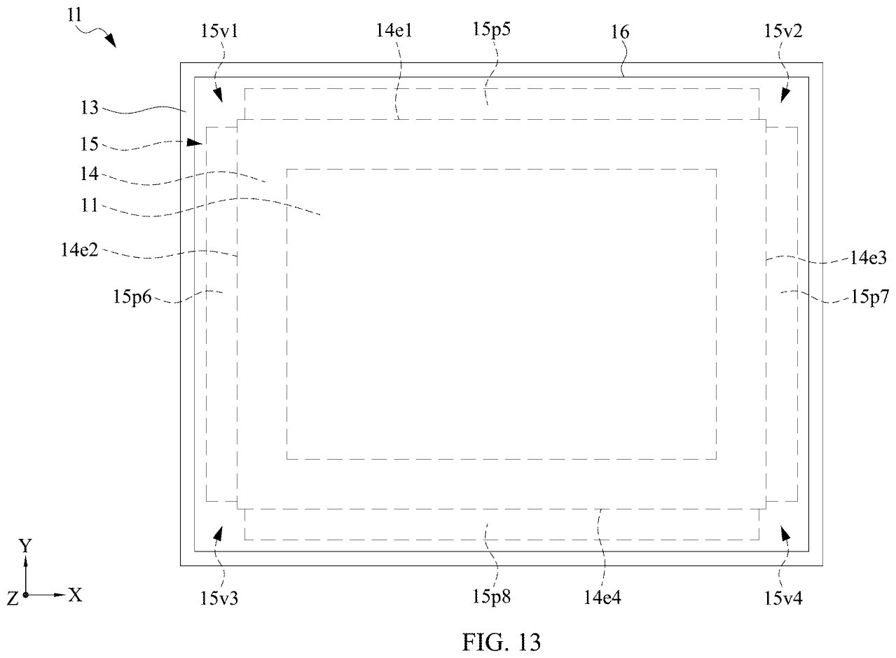

FIG. 13 illustrates a top view of a package structure 1l according to some embodiments of the present disclosure. The package structure 1l is similar to the package structure 1a as shown in FIG. 1, and the differences therebetween are described below.

The adhesive layer 15 may have segments 15p5, 15p6, 15p7, and 15p8. Each of the segments 15p5, 15p6, 15p7, and 15p8 may have a strip-shaped profile. In some embodiments, the segments 15p5, 15p6, 15p7, and 15p8 of the adhesive layer 15 may define a plurality of openings (or channels) 15v1, 15v2, 15v3, and 15v4. Each of the openings (or channels) 15v1, 15v2, 15v3, and 15v4 may be located at a corresponding corner of the thermal conductive layer 14. For example, the opening (or channel) 15v1 of the adhesive layer 15 may be located at the corner defined by the sides 14e1 and 14e2 of the thermal conductive layer 14.

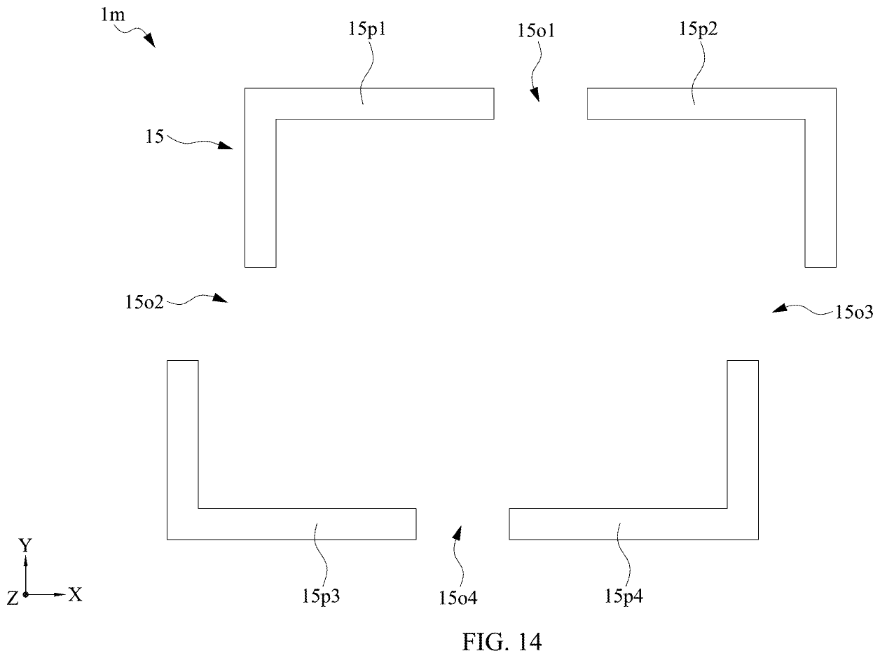

FIG. 14 illustrates a top view of a layout of an adhesive layer 15 of a package structure Im according to some embodiments of the present disclosure. It should be noted that some features are omitted for brevity.

In some embodiments, the opening (or channel) 15o1 may be misaligned with the opening (or channel) 15o4 along the Y direction. In some embodiments, the opening (or channel) 1502 may be misaligned with the opening 15o3 (or channel) along the Y direction. In some embodiments, a portion of the segment 15p3 may be free from overlapping the segment 15p1 along the Y direction.

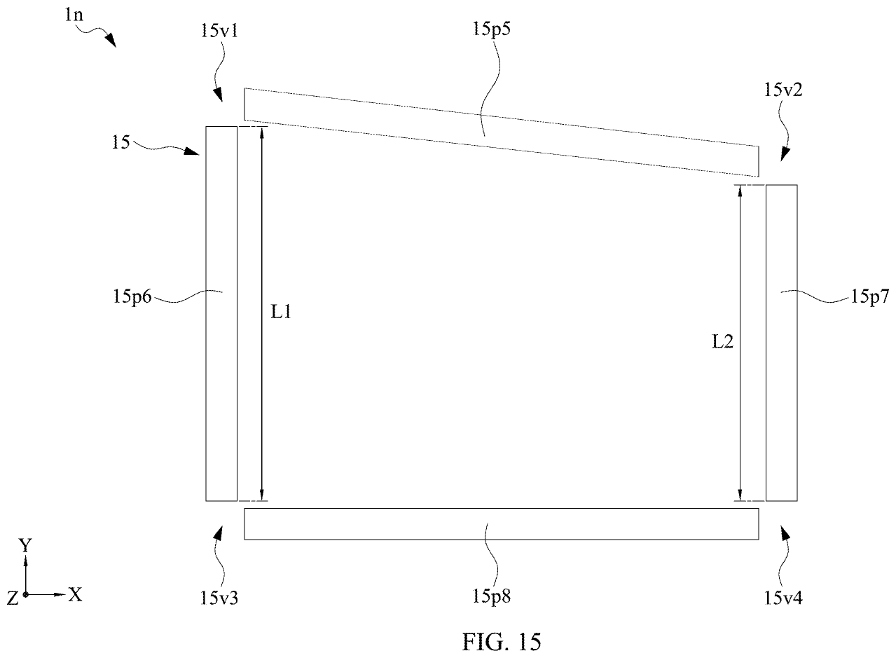

FIG. 15 illustrates a top view of a layout of an adhesive layer 15 of a package structure 1n according to some embodiments of the present disclosure. It should be noted that some features are omitted for brevity.

In some embodiments, the segment 15p5 may extend along a direction slanted with respect to that of the segment 15p8. The segment 15p6 may have a length L1 along the Y direction. The segment 15p7 may have a length L2 along the Y direction. In some embodiments, the length L1 may be different from the length L2.

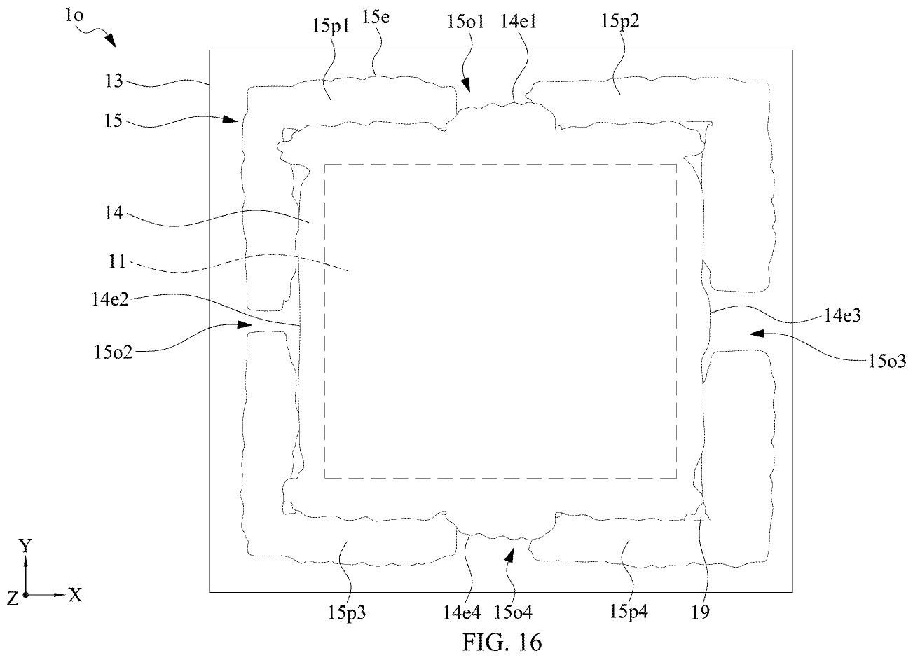

FIG. 16 illustrates a top view of a package structure 1o according to some embodiments of the present disclosure. The package structure 1o is similar to the package structure 1a as shown in FIG. 1, and the differences therebetween are described below.

In some embodiments, a portion of the thermal conductive layer 14 may be located within the opening (or channel) 15o1. In some embodiments, a portion of the thermal conductive layer 14 may be protruded toward the opening (or channel) 15o1. In some embodiments, a portion of the thermal conductive layer 14 may be disposed between the segments 15p1 and 15p2 or disposed within the adhesive layer 15. In some embodiments, the side 14e1 of the thermal conductive layer 14 may include a rough and/or a curved surface. In some embodiments, the edge 15e of the adhesive layer 15 may include a rough and/or curved surface. In some embodiments, a plurality of voids 19 may be located between the thermal conductive layer 14 and the adhesive layer 15.

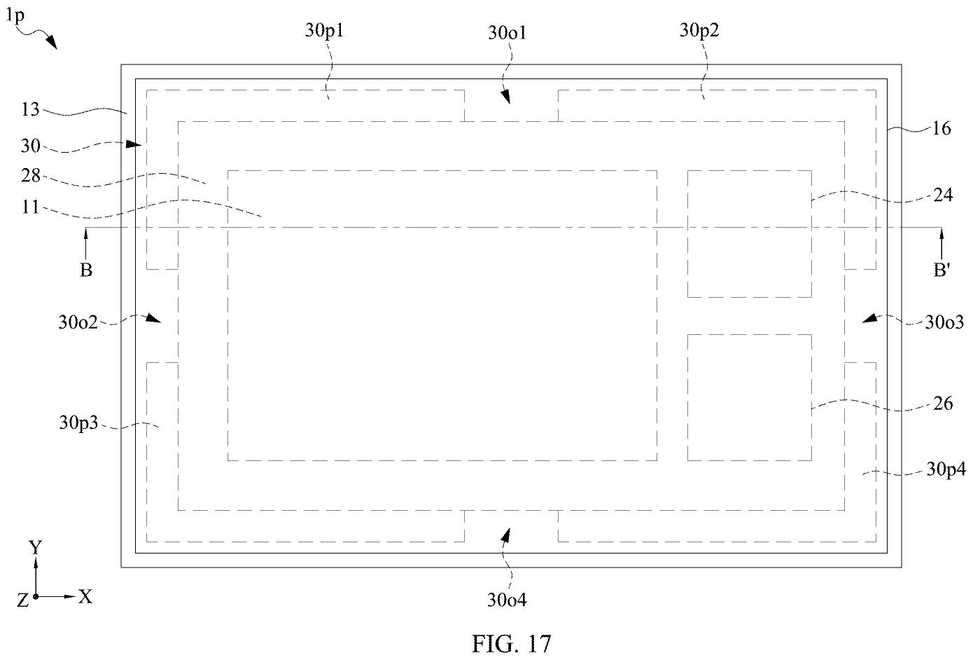

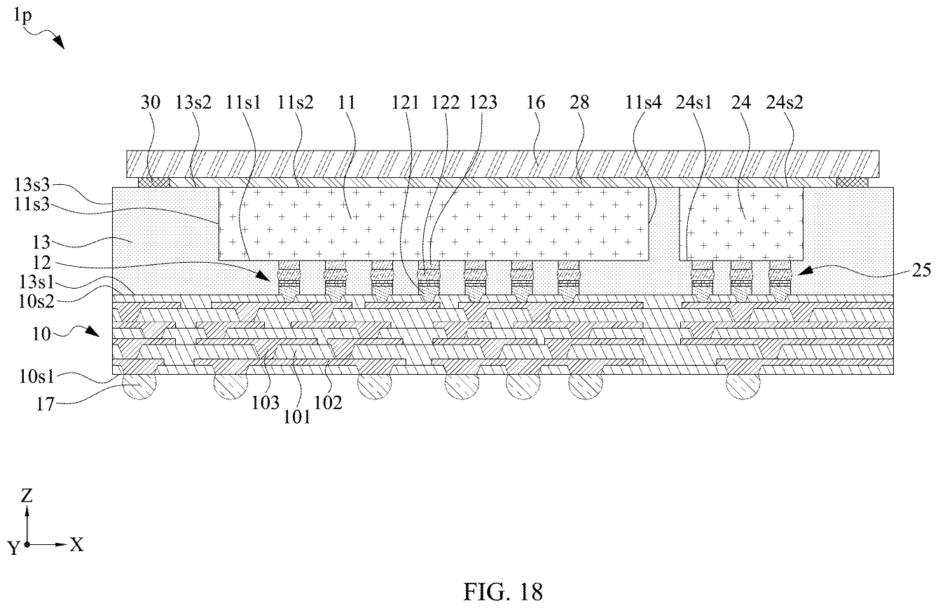

FIG. 17 illustrates a top view of a package structure 1p according to some embodiments of the present disclosure. FIG. 18 illustrates a cross-sectional view taken along line B-B′ of the package structure 1p of FIG. 17. The package structure 1p is similar to the package structure 1a as shown in FIG. 1, and the differences therebetween are described below.

In some embodiments, the package structure 1p may include electronic components 24 and 26. As shown in FIG. 17, the electronic component 24 may have a dimension (e.g., length, width, or area) different from that of the electronic component 11. The electronic component 26 may have a dimension (e.g., length, width, or area) different from that of the electronic component 11. The package structure 1p may include a thermal conductive layer 28 and an adhesive layer 30. The thermal conductive layer 28 may cover the electronic components 11, 24, and 26. In some embodiments, the adhesive layer 30 may include a plurality of segments 30p1, 30p2, 30p3, and 30p4. In some embodiments, the segment 30p1, 30p2, 30p3, and 30p4 may be separated from each other. In some embodiments, the segment 30p1, 30p2, 30p3, and 30p4 of the adhesive layer 30 may define a plurality of openings (or channels) 30o1, 30o2, 30o3, and 30o4. In some embodiments, a portion of the thermal conductive layer 28 may be exposed from the openings (or channels) 30o1, 30o2, 30o3, and 30o4 of the adhesive layer 30.

As shown in FIG. 18, the electronic component 24 may be disposed on or disposed over the surface 10s2 of the carrier 10. The electronic component 24 may be a chip or a die including a semiconductor substrate, one or more IC devices and one or more overlying interconnection structures therein. The IC devices may include active devices such as transistors and/or passive devices such as resistors, capacitors, inductors, or a combination thereof. For example, the electronic component 24 (or 26) may include a high bandwidth memory (HBM) die, RFIC, ASIC, CPU, MPU, GPU, MCU, FPGA, or another type of IC. The electronic component 24 may have a surface 24s1 (or a bottom surface) and a surface 24s2 (or a top surface) opposite to the surface 24s1. The surface 24s1 may face the carrier 10 and function as an active surface of the electronic component 11. In some embodiments, the surface 24s2 of the electronic component 24 may be substantially level with the surface 11s2 of the electronic component 11.

The package structure 1p may include electrical connections 25. The electrical connection 25 may be disposed on or disposed over the surface 24s1 of the electronic component 24. The electrical connection 25 may be configured to electrically connect the carrier 10 and the electronic component 24. The structure, the material, and the function of the electrical connection 25 may be the same as or similar to those of the electrical connection 12.

In some embodiments, the thermal conductive layer 28 may be disposed on or disposed over the surface 11s2 of the electronic component 11. In some embodiments, the thermal conductive layer 28 may be disposed on or disposed over the surface 24s2 of the electronic component 24. In some embodiments, the thermal conductive layer 28 may fully cover the surface 11s2 of the electronic component 11 and the surface 24s2 of the electronic component 24. In some embodiments, the thermal conductive layer 28 may continuously extend from the surface 11s2 of the electronic component 11 to the surface 24s2 of the electronic component 24. The structure, the material, and the function of the thermal conductive layer 28 may be the same as or similar to those of the thermal conductive layer 14.

In some embodiments, the adhesive layer 30 may be disposed on or disposed over the surface 13s2 of the encapsulant 13. In some embodiments, the adhesive layer 30 may be disposed along the surface 13s3 (or an edge) of the encapsulant 13. In some embodiments, the adhesive layer 30 may surround or around the thermal conductive layer 28. In some embodiments, the adhesive layer 30 may be free from vertically overlapping the electronic components 11 and 24. The structure, the material, and the function of the adhesive layer 30 may be the same as or similar to those of the adhesive layer 15. In some embodiments, the adhesive layer 30 may be configured to attach the encapsulant 13 to the heat dissipating element 16 to reduce a warpage of the package structure 1p.

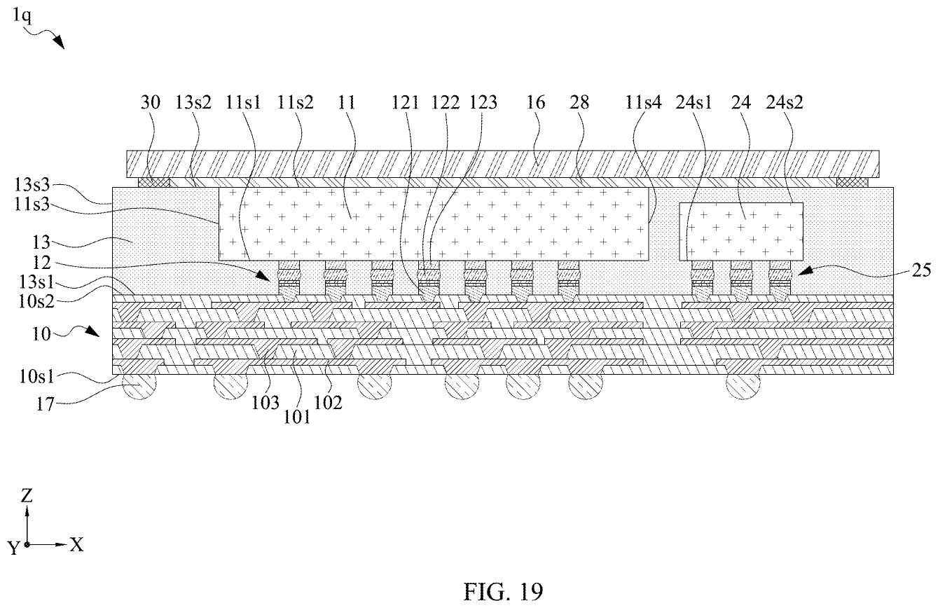

FIG. 19 illustrates a cross-sectional view of an example of a package structure 1q according to some embodiments of the present disclosure. The package structure 1q is similar to the package structure 1p as shown in FIG. 18, and the differences therebetween are described below.

In some embodiments, the surface 24s2 of the electronic component 24 may be spaced apart from the thermal conductive layer 28. In some embodiments, a portion of the encapsulant 13 may be disposed between the conductive layer 28 and the surface 24s2 of the electronic component 24. In some embodiments, the surface 11s2 of the electronic component 11 may be located at an elevation different from that of the surface 24s2 of the electronic component 24. In some embodiments, the surface 11s2 of the electronic component 11 may be higher than the surface 24s2 of the electronic component 24.

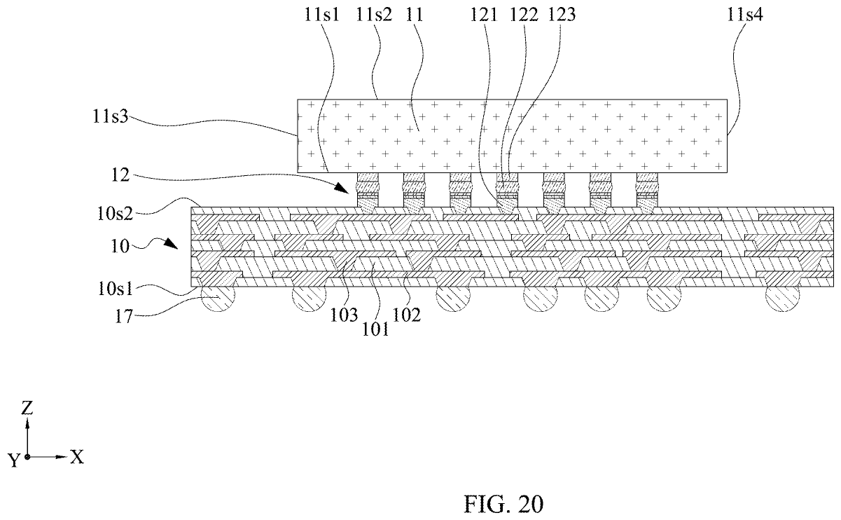

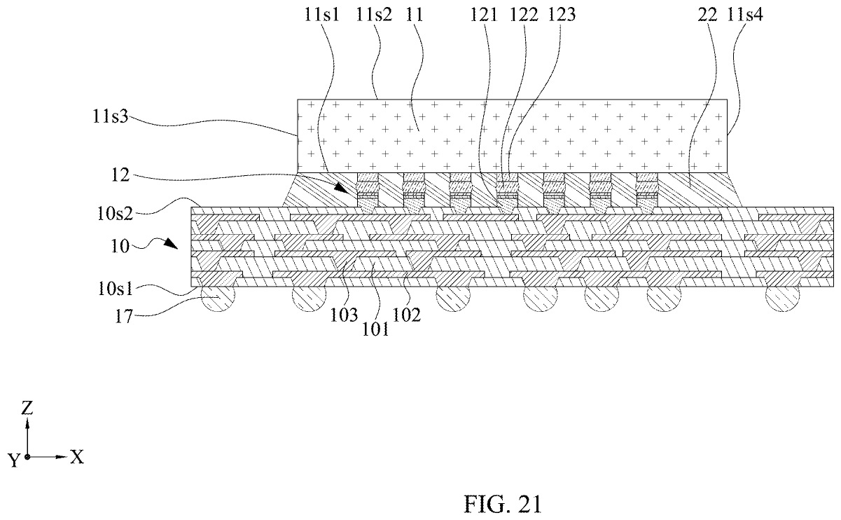

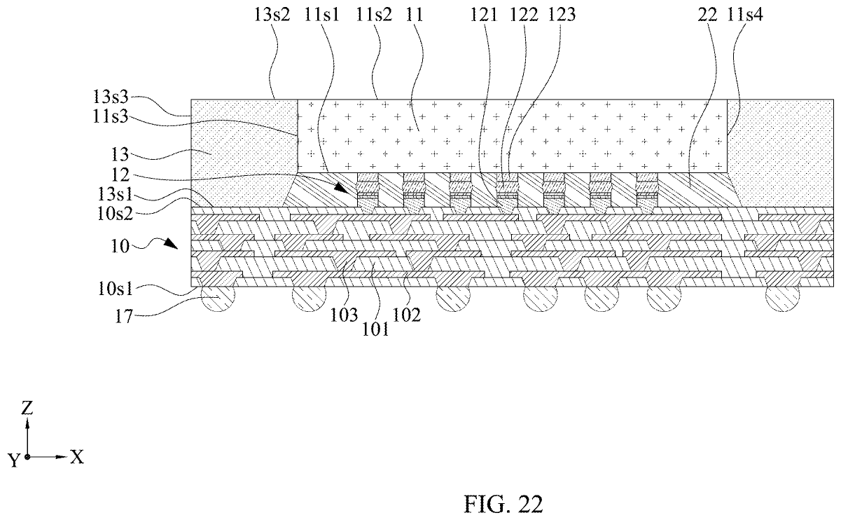

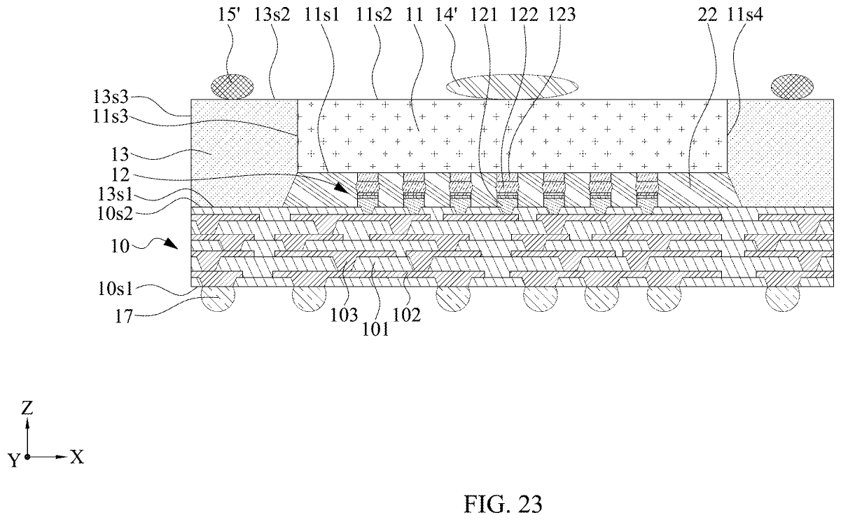

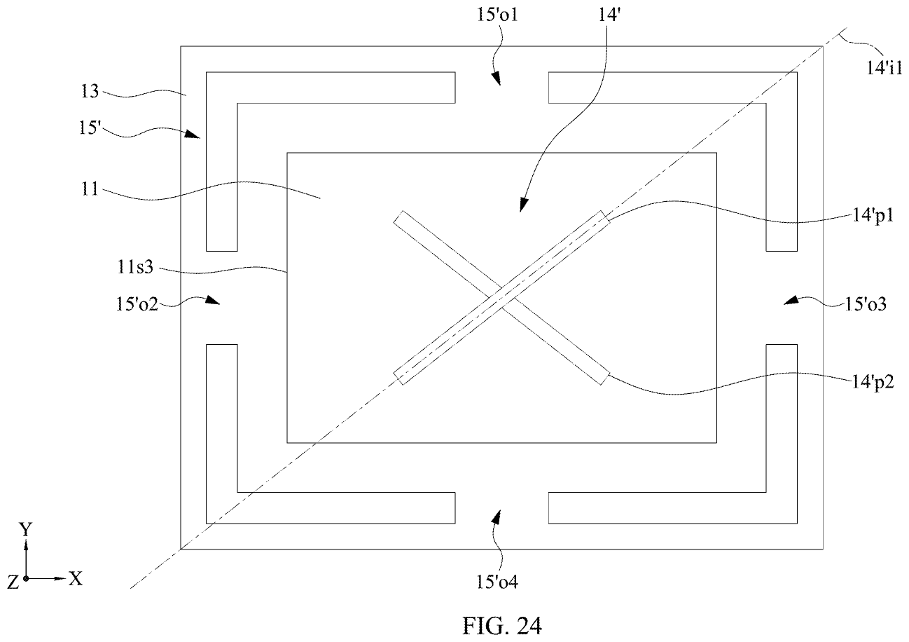

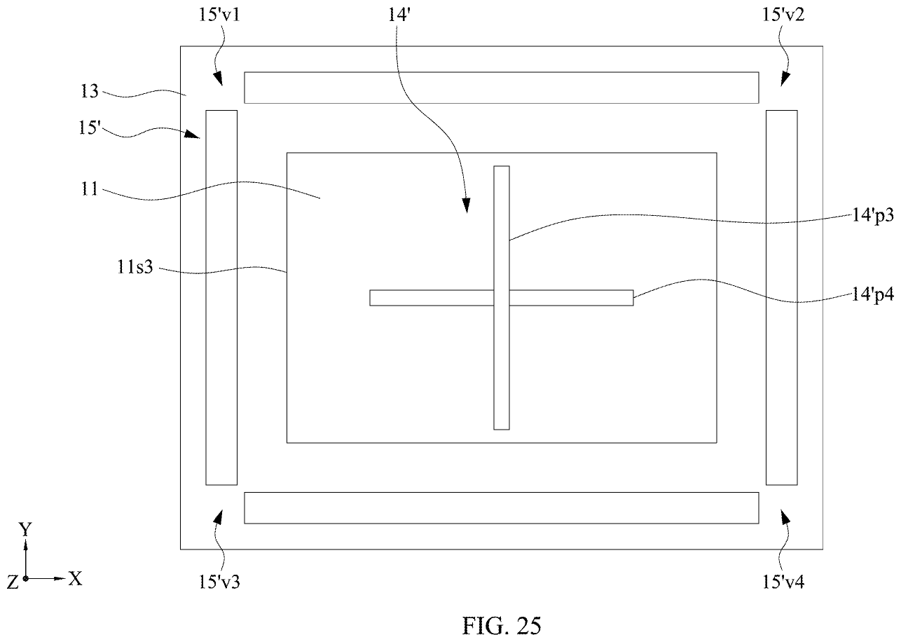

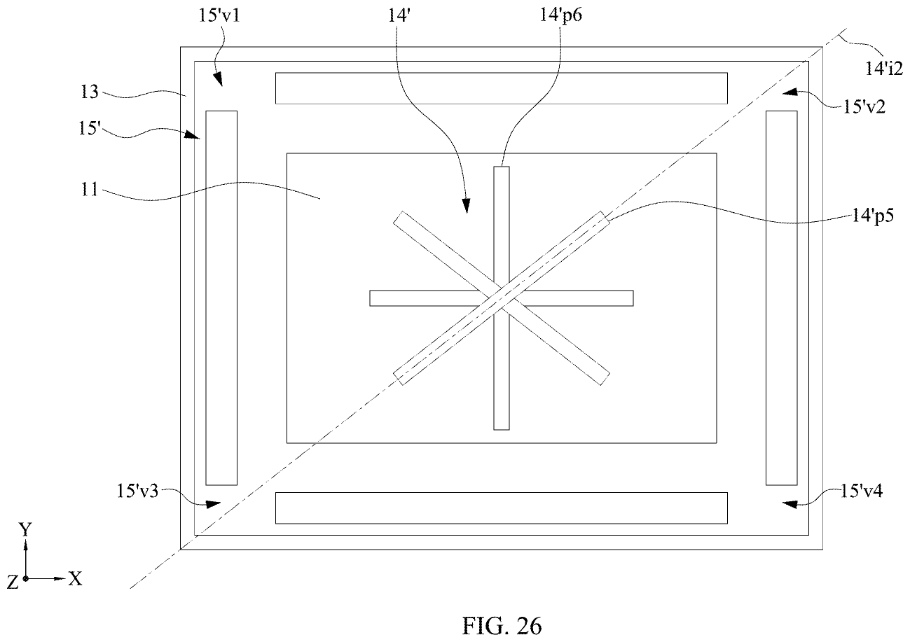

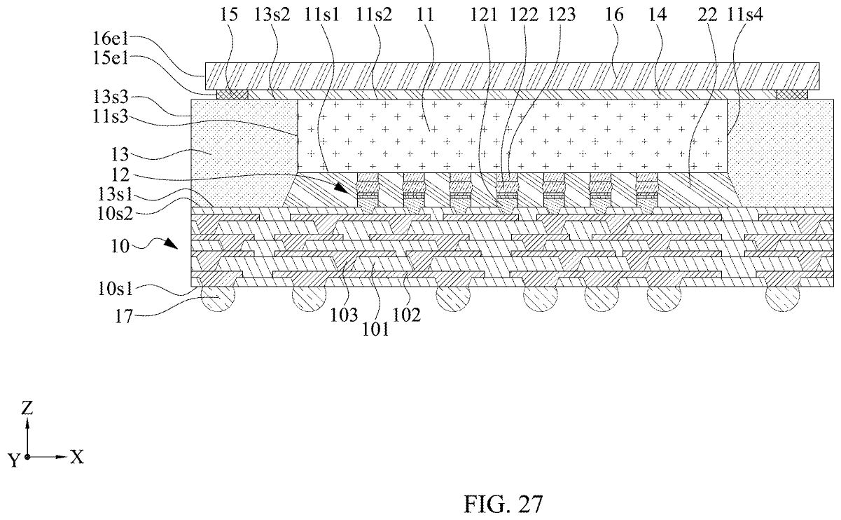

FIG. 20, FIG. 21, FIG. 22, FIG. 23, and FIG. 27 illustrates various stages of an example of a method for manufacturing a package structure according to some embodiments of the present disclosure. Each of FIG. 24, FIG. 25, and FIG. 26 illustrates a top view of a layout of an adhesive material and a thermal conductive material at the stage as shown in FIG. 23 according to some embodiments of the present disclosure. In some embodiments, the method is for manufacturing the package structure 1f as shown in FIG. 7.

Referring to FIG. 20, a carrier 10 may be provided. An electronic component 11 may be attached to the surface 10s2 of the carrier 10. The electrical connections 12, including pads 121, conductive elements 122, and electrical contacts 123, may be formed so that the carrier 10 may be electrically connected to the electronic component 11. A plurality of electrical connections 17 may be formed on or formed over the surface 10s1 of the carrier 10.

Referring to FIG. 21, a protection layer 22 may be formed between the surface 11s1 of the electronic component 11 and the surface 10s2 of the carrier 10 to encapsulate the electrical connections 12.

Referring to FIG. 22, an encapsulant 13 may be formed on or formed over the surface 10s2 of the carrier 10 to encapsulate the electronic component 11 and the protection layer 22.

Referring to FIG. 23, a thermal conductive material 14′ may be formed on or formed over the surface 11s2 of the electronic component 11. An adhesive material 15′ (or a block layer) may be formed on or formed over the surface 13s2 of the encapsulant 13. The thermal conductive material 14′ may be configured to form the thermal conductive layer 14 after the thermal conductive material 14′ is heated and/or cured. The adhesive material 15′ may be configured to form the adhesive layer 15 after the adhesive material 15′ is heated and/or cured.

Referring to FIG. 24, the thermal conductive material 14′ may have a part 14′p1 and a part 14′p2. The part 14′p1 may extend along a direction different from that of the part 14′p2. The part 14′p1 may extend along a direction slanted with respect to the surface 11s3 of the electronic component 11. The part 14′p2 may extend along a direction slanted with respect to the surface 11s3 of the electronic component 11. In this stage, the adhesive material 15′ may function as a block layer, which is configured to accumulate the thermal conductive material 14′, including the parts 14′p1 and 14′p2, toward the lateral surface (e.g., surface 11s3) of the electronic component 11. The adhesive material 15′ may include a plurality of segments (not annotated), which may correspond to segments 15p1, 15p2, 15p3, and 15p4 as shown in FIG. 1. The parts of the adhesive material 15′ may define a plurality of openings (or channels) 15′o1, 15′o2, 15′o3, and 15′o4. The openings (or channels) 15′o1, 15′o2, 15′o3, and 15′o4 may be configured to allow gas, generated during heating and/or curing the thermal conductive material 14′ and the adhesive material 15′, to pass through. Therefore, the voids may be reduced within the conductive layer 14 during heating and/or curing the thermal conductive material 14′ and the adhesive material 15′. In some embodiments, an imaginary extension line 14′i1 of the part 14′p1 of the thermal conductive material 14′ may pass through the adhesive material 15′. In some embodiments, the imaginary extension line 14′i1 of the part 14′p1 of the thermal conductive material 14′ may be free from passing the openings (or channels) 15′o1, 15′o2, 15′o3, and 15′o4 of the adhesive material 15′.

Referring to FIG. 25, in other embodiments, the thermal conductive material 14′ may have a part 14′p3 and a part 14′p4. The part 14′p3 may extend along a direction different from that of the part 14′p4. The part 14′p3 may extend along a direction substantially parallel to the surface 11s3 of the electronic component 11. The adhesive material 15′ may define a plurality of openings (or channels) 15′v1, 15′v2, 15′v3, and 15′v4. The openings (or channels) 15′v1, 15′v2, 15′v3, and 15′v4 may be configured to reduce voids during heating and/or curing the thermal conductive material 14′ and the adhesive material 15′.

Referring to FIG. 26, in other embodiments, the thermal conductive material 14′ may include a plurality of parts. For example, the thermal conductive material 14′ may include a part 14′p5 and a part 14′p6 slanted with respect to the part 14′p5. The part 14′p5 may extend along a direction slanted with respect to the surface 11s3 of the electronic component 11. The part 14′p6 may extend along a direction substantially parallel to the surface 11s3 of the electronic component 11. In some embodiments, an imaginary extension line 14′i2 of the part 14′p5 of the thermal conductive material 14′ may pass through the openings (or channels) 15′v2 and 15′v3. In some embodiments, the imaginary extension line 14′i2 of the part 14′p5 of the thermal conductive layer 14 may be free from passing the adhesive material 15′.

Referring to FIG. 27, the thermal conductive material 14′ and the adhesive material 15′ may be heated and/or cured, and the thermal conductive layer 14 and the adhesive layer 15 may be formed. The heat dissipating element 16 may be formed on or formed over the thermal conductive layer 14 and the adhesive layer 15. As a result, a package structure, such as the package structure 1f as shown in FIG. 7, may be produced.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only and that practical implementations of the structures described herein can be spatially arranged in any orientation or manner, provided that the merits of arrangements of this disclosure are not deviated from by such an arrangement.

As used herein, the term “vertical” is used to refer to upward and downward directions, whereas the term “horizontal” refers to directions transverse to the vertical directions.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to #1°, less than or equal to ±0.5°, less than or equal to ±0.1°, or less than or equal to ±0.05°.

Two surfaces can be deemed to be coplanar or substantially coplanar if a displacement between the two surfaces is no exceeding 5 μm, no exceeding 2 μm, no exceeding 1 μm, or no exceeding 0.5 μm. A surface can be deemed to be substantially flat if a displacement between the highest point and the lowest point of the surface is no exceeding 5 μm, no exceeding 2 μm, no exceeding 1 μm, or no exceeding 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity exceeding approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
an electronic component;
a heat dissipating element disposed over the electronic component; and
an adhesive layer disposed between the electronic component and the heat dissipating element and spaced apart from the electronic component by a first space, wherein the first space is configured to reduce a thermal conductive region between the electronic component and the heat dissipating element occupied by the adhesive layer.

2. The package structure of claim 1, wherein the adhesive layer is free from overlapping the electronic component from a top view.

3. The package structure of claim 2, further comprising:
a thermal conductive layer disposed between the electronic component and the heat dissipating element, wherein the thermal conductive layer overlaps the electronic component and accommodated by the adhesive layer.

4. The package structure of claim 3, wherein the thermal conductive layer exceeds an edge of the electronic component from a top view.

5. The package structure of claim 1, further comprising:
an encapsulant encapsulating the electronic component, wherein the electronic component is exposed from a top surface of the encapsulant, and the adhesive layer is disposed over the encapsulant.

6. The package structure of claim 5, wherein the adhesive layer includes a first portion overlapping the electronic component along a direction substantially parallel to the top surface of the encapsulant.

7. The package structure of claim 6, further comprising:
a thermal conductive layer disposed between the electronic component and the heat dissipating element, wherein a second space is defined between the first portion of the adhesive layer and the electronic component along the direction, and the thermal conductive layer includes a second portion located within the second space and is configured to guide a heat located at a lateral surface of the electronic component to the heat dissipating element.

8. The package structure of claim 7, wherein the second portion of the thermal conductive layer is further configured to guide a heat located within encapsulant to the heat dissipating element.

9. The package structure of claim 5, wherein the adhesive layer contacts the encapsulant and the heat dissipating element, and the adhesive layer is configured to reduce a warpage of the package structure.

10. The package structure of claim 9, wherein a coefficient of thermal expansion of the heat dissipating element is less than a coefficient of thermal expansion of the encapsulant.

11. The package structure of claim 1, wherein in a top view, the adhesive layer includes a plurality of segments defining at least one channel configured to reduce voids between the adhesive layer and the thermal conductive layer.

12. The package structure of claim 11, wherein in the top view, one of the plurality of segments of the adhesive layer is in an L shape.

13. The package structure of claim 11, wherein a portion of the thermal conductive layer is located within the at least one channel.

14. A package structure, comprising:
an electronic component including a top surface and a lateral surface abutting the top surface;
an encapsulant encapsulating the electronic component and having a first surface exposing a top surface of the electronic component, wherein an elevation of a first portion of the first surface is lower than that of the top surface of the electronic component;
a heat dissipating element disposed over the first surface of the encapsulant;
a thermal conductive layer disposed over the first portion of the encapsulant and abutting the lateral surface of the electronic component, and configured to guide a heat generated from the lateral surface of the electronic component to the heat dissipating element; and
a block layer abutting the lateral surface of the electronic component.

15. The package structure of claim 14, wherein in a top view, the block layer is disposed along an interface between the electronic component and the encapsulant.

16. The package structure of claim 14, wherein the thermal conductive layer comprises a first portion having a first thickness and a second portion having a second thickness greater than the first thickness, and the second portion of the thermal conductive layer is closer to the block layer than the first portion of the thermal conductive layer is.

17. The package structure of claim 16, wherein an inner surface of the block layer is concave toward an outer lateral surface of the block layer.

18. The package structure of claim 14, wherein from a cross-sectional view, the block layer comprises a first portion located at a first side of the electronic component and a second portion located at a second side of the electronic component, and a thickness of the first portion of the block layer is different from that of the second portion of the block layer.

19. The package structure of claim 18, wherein the heat dissipating element has a bottom surface facing the electronic component, and the bottom surface of the heat dissipating element is noncoplanar with the top surface of the electronic component.

20. The package structure of claim 14, further comprising:
an electrical connection encapsulated by the encapsulant and connected to the block layer.
